(19) United States
(12) Patent Application Publication
(10) Pub. No.: US 2007/0163802 A1
(43) Pub. Date: Jul. 19, 2007

(54) Electronic package including an electromagnetic shield

(75) Inventor: Dean L. Monthei, Beaverton, OR (US)

Correspondence Address: Joe Pugh;TriQuint Semiconductors, Inc., 2300 N.E. Brookwood Parkway, Hillsboro, OR, 97124, US

(73) Assignee: TriQuint Semiconductors, Inc.

(21) Appl. No.: 11/335,218

(22) Filed: Jan. 19, 2006

(51) Int. Cl. H05K 9/00

(52) U.S. Cl. 174/350

(57) ABSTRACT

One embodiment of n electromagnetically shielded electronic package includes a substrate having an exposed surface, a grounding structure at least partially exposed on the exposed surface and at least one electrical component positioned on the exposed surface, a conductive structure secured to the exposed surface and in contact with the grounding structure, a non-conductive layer formed on the exposed surface and covering the at least one electrical component and at least partially covering the conductive structure, and a conductive layer formed on the non-conductive layer and in contact with the conductive structure.

### BACKGROUND

An electronic package may include electromagnetic shields to reduce radiation from circuits inside the package or to reduce damage to electrical components inside the package from external radiation sources. Currently, most electromagnetic shields are added as a separately soldered on metallic cover over the electronic package or embedded inside. The process of adding the shield to a package may be time consuming, costly, and add physical size and weight to the package. Accordingly, it may be desirable to provide an integrated electromagnetic shield on an electronic package in a time and cost efficient and compact manner.

### BRIEF DESCRIPTION OF THE DRAWINGS

FIG. 1 is a schematic cross-sectional side view of one embodiment of an electronic package including a conductive structure and an electrical component positioned within a non-conductive layer formed on a top surface of an interconnect substrate.

FIG. 2 is a schematic cross-sectional side view of the electronic package of FIG. 1 having a top region of the non-conductive layer removed to expose a portion of the conductive structure.

FIG. 3 is a schematic cross-sectional side view of the integrated circuit package of FIG. 2 having a conductive layer formed on top of the non-conductive layer and in contact with the conductive structure.

FIG. 4 is a flowchart showing one method of manufacturing an integrated circuit including an electromagnetic shield.

FIG. 5 is a schematic cross-sectional side view of another embodiment of an electronic package having a conductive layer formed on top of a non-conductive layer and in contact with a conductive structure.

FIG. 6 is a schematic cross-sectional side view of another embodiment of an electronic package having a conductive layer formed on top of a non-conductive layer and in contact with a conductive structure.

### DETAILED DESCRIPTION OF THE DRAWINGS

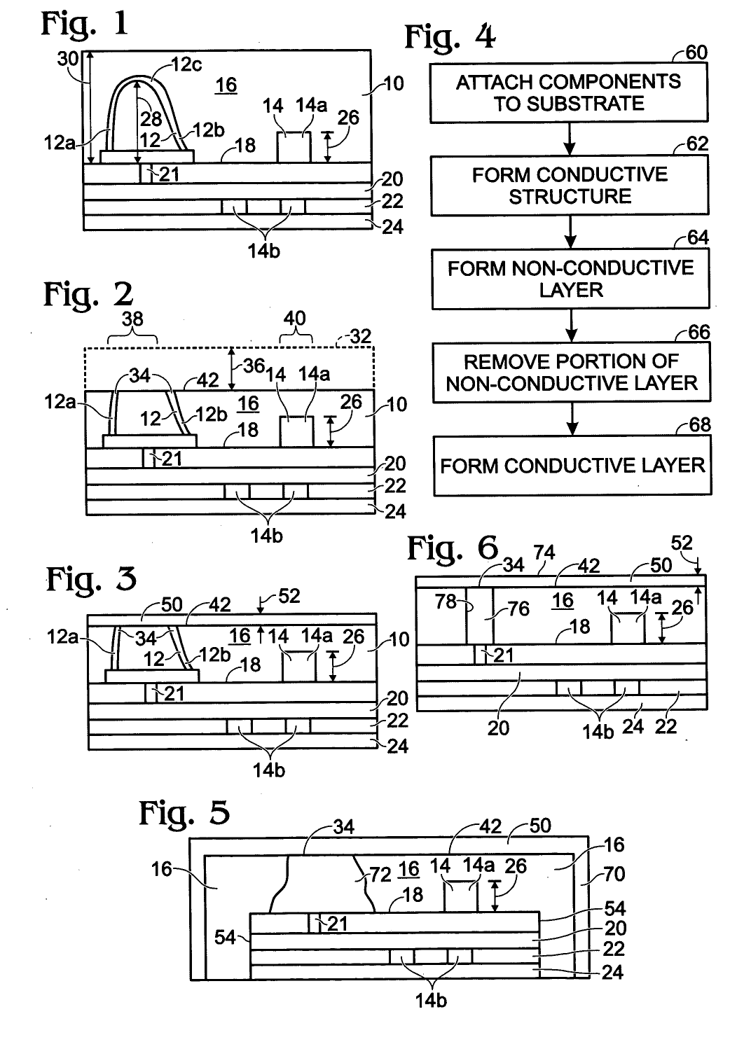

FIG. 1 is a schematic cross-sectional side view of one embodiment of an electronic package 10 including a conductive structure 12, integrated circuit die and surface mount electrical components 14, such as a component 14a, positioned within a non-conductive layer 16 formed on a surface 18 of the electronic package 10. Surface 18 may be a top surface of a substrate prior to formation of non-conductive layer 16 thereon. Electronic package 10 may be a multi-layer substrate, such as a printed circuit board, a ceramic, such as a low temperature cofired ceramic or a high temperature cofired ceramic, or other substrate including numerous electrical components 14 such as resistors, transistors, capacitors, and the like, wherein electrical components positioned below surface 18 may be designated 14b.

Electronic package 10 may be a layered stack including multiple layers 20, 22, 24 and the like. In one example, layer 20 may be formed of a conductive material and may define a grounding layer. Conductive structure 12 may be connected to grounding layer 20 by a via 21 filled with a conductive material, or by any other connection method. Other layers or portions of other layers, or components thereof, may be electrically connected to grounding layer 20 for electrical grounding purposes. In one example, layer 22 may include multiple electrical components 14b formed therein and layer 24 may be a substrate layer with interconnect pads. In other embodiments, any number, arrangement, functionality, type, or combination thereof of components and/or layers may be utilized as desired for a particular application.

In the embodiment shown in FIG. 1, electronic package 10 includes one or more electrical components 14b positioned within the layered stack of layers 20, 22 and 24, and one or more electrical components 14a positioned on surface 18. Components 14a positioned on surface 18 may extend upwardly a height 26 from surface 18, wherein height 26 may be measured perpendicular to surface 18. Height 26 may be any height and in one embodiment may be in a range of approximately 300 to 500 microns. Component 14a positioned on surface 18 of electronic package 10 may be a integrated circuit die with wire bonds, a resistor, a transistor, a capacitor, or any other type of electrical component or combination of components as may be desired for a particular application.

Conductive structure 12 may also define a height 28 measured perpendicular to surface 18. In one embodiment height 28 may be any height greater than the greatest height 26 of components 14a positioned on surface 18, and may define a height of approximately 100 to 200 microns greater than height 26 of component 14a. In other words, in one embodiment, conductive structure 12 extends upwardly a greater distance than every component 14a positioned on surface 18. For example, height 28 may be in a range of 600 to 700 microns. In other embodiments (see FIG. 5) height 28 of conductive structure 12 may be less than a height 26 of a component 14a positioned on surface 18. In such an embodiment, non-conductive layer 16 may completely enclose component 14a positioned on surface 18 but may be removed in a region above conductive structure 12 so as to expose conductive structure 12.

Conductive structure 12 may comprise a metallic wire, such as gold, copper or aluminum, for example, that may be secured to surface 18 of integrated circuit 10 by any method. In one embodiment, conductive structure 12 may be a length of gold wire that is thermosonically, ultrasonically, or thermocompression wire bonded to surface 18 on each of two ends 12a and 12b of the gold wire to form a loop. The upper most part 12c of the metallic loop of conductive structure 12 may define height 28. In another embodiment (see FIG. 5), conductive structure 12 may be a conductive bump of material formed on surface 18, wherein the height of the bump defines height 28. In still another embodiment (see FIG. 6), conductive structure 12 may be formed by forming a hole or a via that extends through non-conductive layer 16 and then filling the hole or via with a conductive material, wherein the length of the hole or via defines height 28 of the conductive material positioned therein.

Non-conductive layer 16 may define an initial height 30 measured perpendicular to surface 18 that may be greater than height 26 of component 14a positioned on surface 18. In the embodiment shown, initial height 30 of non-conductive layer 30 is also greater than height 28 of conductive structure 12. In one embodiment, height 30 may be greater than approximately 700 microns.

Non-conductive layer 16 may be formed on surface 18 by any method and may be formed of any non-conductive material. In one embodiment non-conductive layer 16 is formed of epoxy mold compound (EMC) which includes ceramic particles blended, initially, into a liquid epoxy. The liquid epoxy material may be deposited on surface 18 by a “transfer molding” technique wherein the liquid epoxy is injected into a mold in a heated chamber. The mold may include the electronic package such that the liquid epoxy is injected onto top surface 18 of electronic package 10 to form layer 16 directly on surface 18. In one method the mold may be heated to a temperature of approximately 175 degrees Celsius during injection of the epoxy. The epoxy is then cured in the chamber after injection into the mold and onto surface 18 of the electronic package 10. In one method the curing step may take place for a time period of approximately 2 minutes at a temperature of approximately 175° C. After curing, the mold part may be removed to reveal non-conductive layer 16 formed on surface 18 and around conductive structure 12 and electrical component or components 14a on surface 18. In another embodiment, after the part is removed from the mold, it may be subjected to an additional curing step, such as baking the part or parts in an oven for approximately four hours at a temperature of approximately 175° C., wherein this additional curing step may be referred to as a post mold cure. As shown in the embodiment of FIG. 1, non-conductive layer 16 defines an initial height 30 that is greater than a height 26 of component 14a on surface 18 and greater than or equal to a height 28 of conductive structure 12. In one embodiment, height 30 may be approximately 900 microns.

As stated earlier, non-conductive layer 16 is formed directly on surface 18 of electronic package 10. Accordingly, layer 16 may only utilize a sufficient amount of material to cover top surface 18. Additionally, layer 16 may only have a height 30 (also referred to as a thickness) sufficient to enclose components 14a. The height 30 or thickness of layer 16 need not be made thicker to be a self supporting or a stand alone structure. The formation process may also be simply added as a step to the formation process of forming layers 20, 22 and 24, for example, of electronic package 10. Moreover, forming layer 16 directly on surface 18 may be a chemical formation process instead on a mechanical attachment process of a pre-formed structure. Accordingly, formation of conductive layer 50 (see FIG. 3) on insulating or non-conductive layer 16 of electronic package 10 may be more cost effective and less time consuming than prior art electromagnetic shield manufacturing methods.

FIG. 2 is a schematic cross-sectional side view of the electronic package 10 of FIG. 1 having a section 32 (indicated by dash lines) of non-conductive layer 16 removed to expose a portion 34 of conductive structure 12. The amount of section 32 removed may be sufficient to expose a portion 34 of conductive structure 12 but to leave component 14a on top surface 18 completely enclosed within non-conductive layer 16. Accordingly, in the embodiment shown, section 32 removed from non-conductive layer 16 may define a height 36 of approximately 200 microns. Section 32 may be removed by any applicable method such as mechanical grinding, laser ablation, or chemical etching, such as plasma etching. In another embodiment (see FIG. 2), only a region 38 over conductive structure 12 may be removed to expose conductive structure 12 wherein a region 40 over component 14a is not removed. Such a removal method may utilize site specific laser ablation, mechanical machining, or site specific plasma etching. Such site specific exposure of conductive structure 12 may not be preferred if a flat top surface 42 (see FIG. 1) of non-conductive layer 16 is desired for the formation of a conductive layer thereon (see FIG. 3).

FIG. 3 is a schematic cross-sectional side view of the electronic package 10 of FIG. 2 having a conductive layer 50 formed on surface 42 of non-conductive layer 16 and in contact with conductive structure 12. Conductive layer 50 may be formed of any conductive material such as a conductive epoxy, including, for example, silver, copper, or gold particles, or a mixture thereof, in a liquid epoxy. In such an example, the liquid epoxy may be screen printed, i.e., squeegeed, onto surface 42 of non-conductive layer 16. In another example, conductive layer 50 may be rolled onto surface 42 of non-conductive layer 16. In still another embodiment, a thin film of a metal, such as a thin film of copper or gold, may be sputtered or evaporated onto surface 42 of non-conductive layer 16. In other embodiment, any type of conductive layer 50 may be formed on a top surface of integrated surface 42 of electronic package 10. In other embodiments, conductive layer 50 may also be formed along side surfaces 54 (see FIG. 5) of electronic package 10 to provide electromagnetic protection there along. In such an embodiment, non-conductive layer 16 may be formed along side surface 54 (see FIG. 5) of electronic package 10 prior to formation of conductive layer 50 thereon.

As stated earlier, conductive layer 50 is formed directly on electronic package 10, such as on surface 42 of layer 16, or such as on a top surface of an adhesion promotion layer that may be formed on non-conductive layer 16. Accordingly, layer 50 may only utilize a sufficient amount of material to cover surface 42. Additionally, layer 50 may only have a height 52 (also referred to as a thickness) sufficient to cover surface 42. The height 52 or thickness of layer 50 need not be made thicker to be a self supporting or a stand alone structure. The formation process may also be simply added as a step to the formation process of forming layers 20, 22 and 24, for example, of electronic package 10. Moreover, forming layer 50 directly on surface 42 may be a chemical formation process instead on a mechanical attachment process of a pre-formed structure. Accordingly, formation of layer 50 directly on surface 42 of integrated circuit 10 may be more cost effective, less time consuming and result in a smaller physical size and weight than prior art electromagnetic shield manufacturing methods.

FIG. 4 is a flowchart showing one method of manufacturing an electronic package 10 including an electrical shield, such as a conductive layer 50 (see FIG. 3). Step 60 may include manufacturing an electronic package, such as attaching components 14a to a substrate that includes a surface 18, wherein electronic package 10 may include a grounding layer, such as layer 20. Step 62 may include forming a conductive structure 12 on surface 18, wherein conductive structure 12 is electrically connected to grounding layer 20. The step of forming conductive structure 12 may include forming a structure having a height 28 greater than a height 26 of component 14a. Step 64 may include forming a non-conductive layer 16 on surface 18, wherein non-conductive layer 16 completely encloses electronic component 14a. Step 66 may include removing a portion of non-conductive layer 16 to expose a portion of conductive structure 12. Step 68 may include forming a conductive layer on a surface 42 of non-conductive layer 16. This step may include forming conductive layer on a top surface of non-conductive layer 16 and along side surfaces 54 of electronic package 10.

FIG. 5 is a schematic cross-sectional side view of another embodiment of an electronic package 70 having a conductive layer 50 formed on top of a non-conductive layer 16 and in contact with a conductive structure 72. Conductive structure 72 may be a conductive bump manufactured by any bump manufacturing method including the use of a tall surface mount component. Conductive structure 72, in this embodiment, may be a bump of conductive material, such as a bump of gold, aluminum or copper. Manufacturing a conductive structure of a thin wire, as shown in FIG. 1, may be preferred in cases where the quantity of material utilized to manufacture the conductive structure, and a size of the conductive structure, are primary concerns. However, manufacturing a conductive structure of a metallic bump, as shown in FIG. 5, may be preferred in cases where robustness of the electronic package is a primary concern. In this embodiment, non-conductive layer 16 and conductive layer 50 are both shown extending along side surfaces 54 of electronic package 10 such that side surfaces 54, in addition to surface 18, including electrical component 14a thereon, are shielded from electromagnetic radiation. In another embodiment, non-conductive layer 16 may only be positioned on top surface 18 and may not extend downwardly along side surfaces 54. In such an embodiment the layers 20, 22 and 24, for example, of substrate 10 may be patterned layers including metal lines on an insulator wherein the metal lines may not extend to the edge of the package.

FIG. 6 is a schematic cross-sectional side view of another embodiment of an electronic package 74 having a conductive layer 50 formed on top of a non-conductive layer 16 and in contact with a conductive structure 76. Conductive structure 76 may be a via 78 formed within non-conductive layer 16, which is then filled with a conductive material after formation of non-conductive layer 16. In one embodiment, via 78 is formed by selective laser ablation, mechanical machining, or site specific plasma etching. The via 78 may then be filled with a conductive material 76 such as gold, aluminum, copper or conductive adhesive. Manufacturing a conductive structure 76 as a via and then filling the via 78 with conductive material may have some disadvantages, such as non-complete filling of the via with conductive material 78. Accordingly, manufacturing the conductive structure of a thin wire, as shown in FIG. 1, may be preferred.

Other variations and modifications of the concepts described herein may be utilized and fall within the scope of the claims below.

We claim:

1. A shielded electronic package, comprising:
a multi-layer substrate including an exposed surface, a grounding structure at least partially exposed on said exposed surface and at least one electrical component positioned on said exposed surface;
a conductive structure secured to said exposed surface and in contact with said grounding structure;
a non-conductive layer formed on said exposed surface and covering said at least one electrical component and at least partially covering said conductive structure; and
a conductive layer formed on said non-conductive layer and in contact with said conductive structure.

2. The shielded electronic package of claim 1 wherein said conductive structure comprises a wire bonded to said exposed surface.

3. The shielded electronic package of claim 1 wherein said conductive structure comprises a via in said non-conductive layer, said via filled with a conductive material.

4. The shielded electronic package of claim 1 wherein said at least one electrical component is chosen from one of an integrated circuit die, a filter, a resistor, a conductor, an inductor, and a capacitor.

5. The shielded electronic package of claim 1 wherein said non-conductive layer is formed by the process of transfer molding.

6. The shielded electronic package of claim 1 wherein said non-conductive layer is formed of plastic.

7. The shielded electronic package of claim 1 wherein said conductive layer is formed by one of a process of screen printing, spraying, rolling, evaporating, sputtering, plating, and laminating.

8. The shielded electronic package of claim 1 wherein said grounding structure includes a layer of conductive material positioned below said exposed surface.

9. The shielded electronic package of claim 1 further comprising a stack of layers formed on said substrate, wherein a portion of said layers defines said grounding structure, and a portion of said layers defines additional electrical components.

10. The shielded electronic package of claim 1 wherein said conductive layer is not in electrical contact with said at least one electrical component through said non-conductive layer.

11. The shielded electronic package of claim 2 wherein said wire is formed of one of gold, copper, silver and aluminum, and wherein said conductive layer is formed of one of epoxy with silver particles therein, epoxy with copper particles therein, and epoxy with gold particles therein.

12. A shielded electronic assembly, comprising:
a multi-layer substrate including electronic components therein and a ground conductor;
a conductive layer formed on exterior surface of said substrate;
a non-conductive layer positioned between said substrate and said conductive layer wherein said non-conductive layer electrically isolates said conductive layer and said substrate from one another; and
a conductive device that extends through said nonconductive layer and is electrically connected to said ground conductor and to said conductive layer.

13. The assembly of claim 12 wherein said multi-layer substrate defines a side surface, and wherein said conductive layer extends over and covers said side surface.

14. The assembly of claim 12 wherein said multi-layer substrate defines a side surface, and wherein said non-conductive layer and said conductive layer both extend over and cover said side surface.

15. The assembly of claim 12 wherein said non-conductive layer and said conductive layer are both formed directly on said substrate with an absence of an air gap therebetween.

16. The assembly of claim 12 wherein said conductive layer defines an electromagnetic interference shield for said substrate.

17. A microelectronic device, comprising:
a multi-layer stack including a ground layer and a signal layer; and
an electromagnetic shield layer formed directly on the multi-layer stack as a topmost layer.

18. The device of claim 17 wherein said electromagnetic shield layer is formed of a conductive material by one of a process of screen printing, spraying, rolling, evaporating, sputtering, plating, and laminating.

19. The device of claim 17 further comprising a non-conductive layer formed between said multi-layer stack and said electromagnetic shield layer wherein said non-conductive layer electrically separates said multi-layer stack and said electromagnetic shield layer.

20. The device of claim 19 further comprising a conductive connection device that extends from said multi-layer stack, through said non-conductive layer and to said electromagnetic shield layer, wherein said conductive connection device is electrically connected to said ground layer of said multi-layer stack.

21. The device of claim 20 wherein said conductive connection device comprises a wire that is thermosonic wire bonded to said multi-layer stack prior to formation of said non-conductive layer and said electromagnetic shield layer.

22. A method of making a multi-layer substrate including an electromagnetic shield, comprising:
forming a conductive member on a top surface of a multi-layer substrate, said conductive member electrically connected to an electrical ground of said multi-layer substrate;
forming a non-conductive layer on said top surface; and
forming a conductive layer on said non-conductive layer, said conductive layer electrically connected to said conductive member;
wherein said non-conductive layer electrically isolates said multi-layer substrate from said conductive layer.

23. The method of claim 22 wherein said conductive member is formed having a first height measured perpendicular to said top surface, wherein said non-conductive layer is formed having a second height measured perpendicular to said top surface, said second height greater than said first height, said method further comprising reducing said second height of said non-conductive layer in at least a region of said conductive member to expose said conductive member.

24. The method of claim 23 wherein said reducing said second height of said non-conductive layer comprises one of mechanical machining, laser cutting and plasma etching.

25. The method of claim 22 wherein said forming a conductive member comprises one of welding a wire to said top surface, forming a via through said top surface, and forming a metal bump on said top layer.

26. The method of claim 22 wherein said forming a non-conductive layer comprises transfer molding an epoxy material onto said top surface, said non-conductive layer formed having a thickness in a range of 500 to 1500 microns.

27. The method of 23 wherein said first height is in a range of 300 to 1450 microns.

28. A method of making an electromagnetic shield on a multi-layer substrate comprising:
bonding a wire to a top surface of said multi-layer substrate;
forming a non-conductive layer on said top surface, said non-conductive layer at least partially surrounding said wire; and
forming a conductive layer on said non-conductive layer, wherein said wire electrically connects said conductive layer and a ground layer of said multi-layer substrate.

29. The method of claim 28 wherein said forming said non-conductive layer comprises forming said non-conductive layer to a height such that said wire is completely enclosed within said non-conductive layer, said method further comprising exposing a portion of said wire in said non-conductive layer prior to forming said conductive layer such that said conductive layer is formed in electrical connection to said wire.

30. A microelectronic device, comprising:
a substrate including a grounding structure and microelectronic components;
means for electrically isolating said microelectronic components;
means for electromagnetically shielding said microelectronic components; and
means for electrically connecting said grounding structure and said means for electromagnetically shielding, said means for electrically connecting extending through said means for electrically isolating.

31. The device of claim 30 wherein said substrate comprises a printed circuit board including multiple layers, said grounding structure comprises a grounding layer within said printed circuit board, said means for electrically isolating comprises a layer of non-conductive material formed on said substrate, said means for electromagnetically shielding comprises a conductive layer coated on said layer of non-conductive material, and said means for electrically connecting comprises a conductive wire electrically connected to said grounding layer and said conductive layer and extending through said non-conductive layer.
